(19) United States
(12) Patent Application Publication
(10) Pub. No.: US 2026/0150564 A1
(43) Pub. Date: May 28, 2026

(54) ELECTRONIC DEVICE

(71) Applicant: InnoLux Corporation, Miao-Li County (TW)

(72) Inventors: Yuan-Lin WU, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 19/372,319

(22) Filed: Oct. 29, 2025

(30) Foreign Application Priority Data
Nov. 28, 2024 (CN) 202411720796.8

(51) Int. Cl. H10K 59/80; H10H 29/37; H10H 29/41; H10H 29/85; H10H 29/854; H10H 29/855; H10K 59/122; H10K 59/124; H10K 59/38; H10K 59/88; H10K 77/10; H10K 102/00

(52) U.S. Cl. CPC H10K 59/879; H10H 29/37; H10H 29/41; H10H 29/8508; H10H 29/8517; H10H 29/854; H10H 29/8552; H10K 59/122; H10K 59/124; H10K 59/38; H10K 59/873; H10K 59/878; H10K 59/8792; H10K 59/88; H10K 77/111; H10K 2102/311; H10K 2102/351

(57) ABSTRACT

An electronic device including a substrate, a first organic layer, a first electronic element, a second organic layer and a first lens is disclosed. The substrate includes a connection portion and at least two main portions, and the connection portion is connected to the at least two main portions. The first organic layer is disposed on one of the at least two main portions and includes a first opening. The first electronic element is disposed in the first opening. The second organic layer is disposed on the first organic layer and covers the first electronic element. The first lens is disposed on the second organic layer.

### BACKGROUND OF THE DISCLOSURE

### 1. Field of the Disclosure

The present disclosure relates to an electronic device, and more particularly to an electronic device including a lens disposed corresponding to an electronic element.

### 2. Description of the Prior Art

In recent years, the technology of electronic products has developed rapidly. Stretchable, foldable, and/or curved electronic devices have become increasingly important in various electronic applications. For example, an electronic device that is bent to have a curved surface may serve as a display device or have other suitable uses. As users'expectations for electronic products continue to rise, improving the performance and product reliability of flexible electronic devices remains a significant issue in the field.

### SUMMARY OF THE DISCLOSURE

One of objectives of the present disclosure is to provide an electronic device, wherein a first lens is disposed corresponding to an electronic element to provide a light-converging effect, thereby improving the luminous efficiency of the electronic device.

An embodiment of the present disclosure provides an electronic device. The electronic device includes a substrate, a first organic layer, a first electronic element, a second organic layer and a first lens. The substrate includes a connection portion and at least two main portions, and the connection portion is connected to the at least two main portions. The first organic layer is disposed on one of the at least two main portions and includes a first opening. The first electronic element is disposed in the first opening. The second organic layer is disposed on the first organic layer and covers the first electronic element. The first lens is disposed on the second organic layer.

An embodiment of the present disclosure provides an electronic device. The electronic device includes a substrate, a circuit layer, a first electronic element and a first lens. The circuit layer is disposed on the substrate and includes a first portion, a second portion, and a gap disposed between the first portion and the second portion. The first electronic element is disposed on the substrate and electrically connected to one of the first portion and the second portion. The first lens is disposed on the first electronic element. The gap extends along a first direction, and a diameter of the first lens is greater than a width of the gap in a second direction perpendicular to the first direction.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a partial top view schematic diagram of an electronic device in different states according to a first embodiment of the present disclosure.

FIG. 2 is a partial cross-sectional schematic diagram of an electronic device according to a first embodiment of the present disclosure.

FIG. 3 is a schematic diagram showing an electronic device according to an embodiment of the present disclosure installed in a vehicle.

FIG. 4 is a partial top view schematic diagram of some variant embodiments of an electronic device according to a first embodiment of the present disclosure.

FIG. 5 is a partial cross-sectional schematic diagram of a variant embodiment of an electronic device according to a first embodiment of the present disclosure.

FIG. 6 is a partial cross-sectional schematic diagram of another variant embodiment of an electronic device according to a first embodiment of the present disclosure.

FIG. 7 is a partial cross-sectional schematic diagram of still another variant embodiment of an electronic device according to a first embodiment of the present disclosure.

FIG. 8 is a partial cross-sectional schematic diagram of an electronic device according to an embodiment of the present disclosure.

FIG. 9 is a partial top view schematic diagram of an electronic device according to a second embodiment of the present disclosure.

FIG. 10 is a partial cross-sectional schematic diagram of an electronic device according to a second embodiment of the present disclosure.

FIG. 11 is a partial top view schematic diagram of an electronic device according to a third embodiment of the present disclosure.

FIG. 12 is a partial cross-sectional schematic diagram of an electronic device according to a third embodiment of the present disclosure.

FIG. 13 is a partial top view schematic diagram of an electronic device according to a fourth embodiment of the present disclosure.

FIG. 14 is a partial cross-sectional schematic diagram of an electronic device according to a fourth embodiment of the present disclosure.

FIG. 15 is a partial top view schematic diagram of an electronic device according to a fifth embodiment of the present disclosure.

FIG. 16 is a schematic diagram of an electronic device according to a sixth embodiment of the present disclosure.

FIG. 17 is a partial cross-sectional schematic diagram of an electronic device according to a sixth embodiment of the present disclosure.

FIG. 18 is a partial top view schematic diagram of a variant embodiment of an electronic device according to a sixth embodiment of the present disclosure.

FIG. 19 is a partial top view schematic diagram of another variant embodiment of an electronic device according to a sixth embodiment of the present disclosure.

FIG. 20 is a partial top view schematic diagram of still another variant embodiment of an electronic device according to a sixth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. The present disclosure does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in the present disclosure, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” generally mean being within 20% of a given value or range, or being within 10%, 5%, 3%, 2%, 1% or 0.5% of a given value or range.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may be applied to a display device, a light-emitting device, a backlight device, an antenna device, a sensing device or a tiled device, but not limited herein. The electronic device may include a bendable or flexible electronic device. The display device may include a non-self-emissive display device or a self-emissive display device. The antenna device may include a liquid-crystal type antenna device or an antenna device other than liquid-crystal type, and the sensing device may include a sensing device used for sensing capacitance, light, heat or ultrasonic waves, but not limited herein. The electronic device may include electronic elements such as passive elements and active elements, for example, capacitors, resistors, inductors, diodes, transistors, etc. The diode may include a light-emitting diode or a photodiode. For example, the light-emitting diode may include an organic light-emitting diode (OLED), a mini light-emitting diode (mini LED), a micro light-emitting diode (micro LED) or a quantum dot light-emitting diode (quantum dot LED), but not limited herein. The tiled device may be, for example, a display tiled device or an antenna tiled device, but not limited herein. It should be noted that the electronic device may be any arrangement and combination of the above, but not limited herein. The electronic device may have a peripheral system such as a driving system, a control system, a light source system, etc., to support a display device, an antenna device, a wearable device (including an augmented reality device or a virtual reality device, for example), a vehicle-mounted device (including an automobile windshield, for example) or a tiled device.

It should be noted that the technical features in different embodiments described in the following can be replaced, recombined, or mixed with one another to constitute another embodiment without departing from the spirit of the present disclosure.

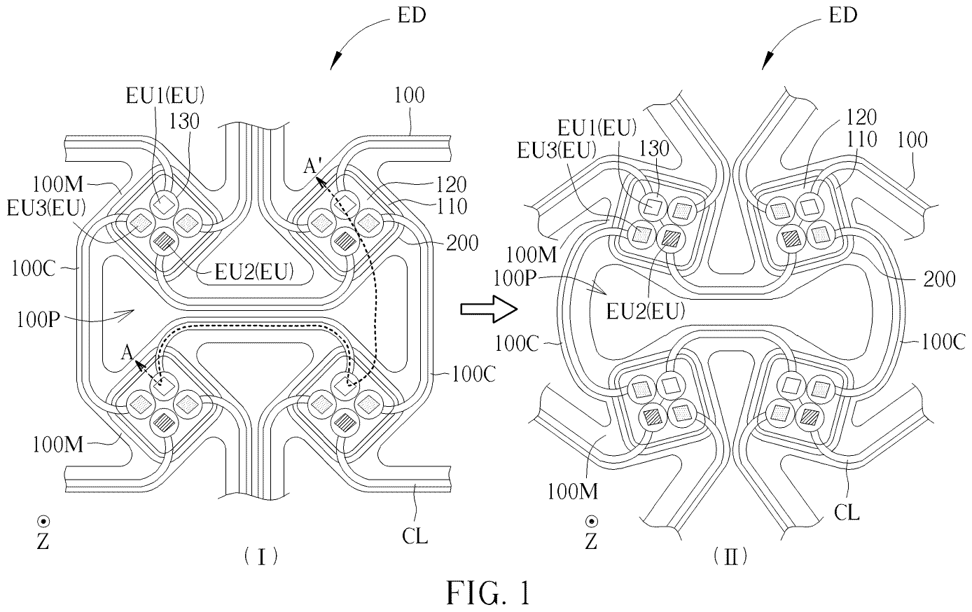

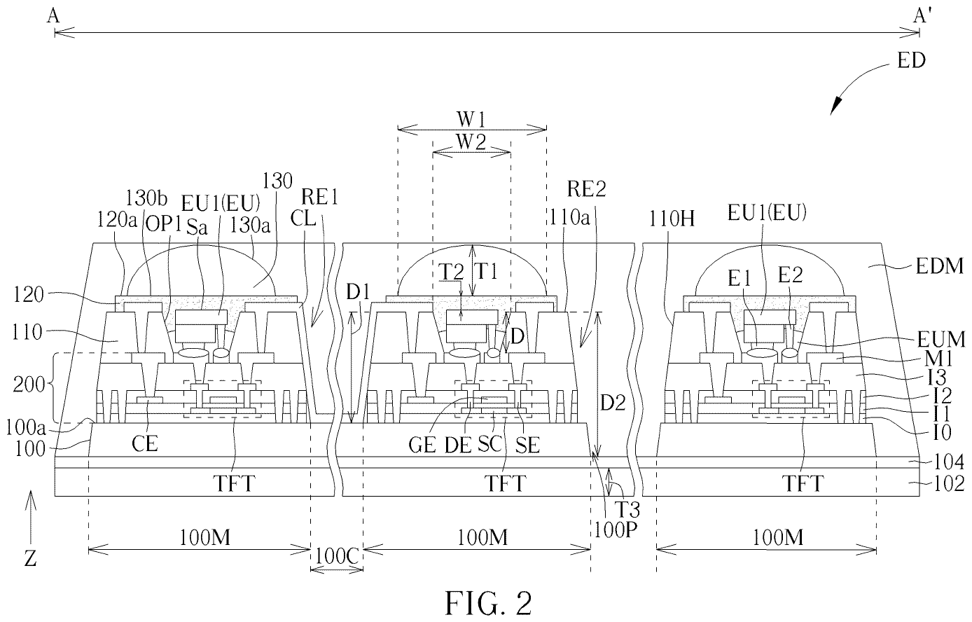

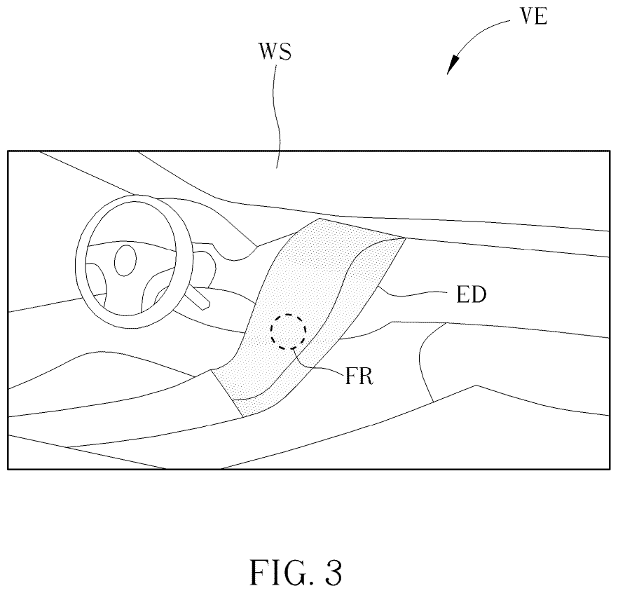

Please refer to FIG. 1 and FIG. 2. FIG. 1 is a partial top view schematic diagram of an electronic device in different states according to a first embodiment of the present disclosure. FIG. 2 is a partial cross-sectional schematic diagram of an electronic device according to a first embodiment of the present disclosure, wherein FIG. 2 is a cross-sectional view corresponding to the section line A-A′ in FIG. 1. As shown in FIG. 1 and FIG. 2, an electronic device ED includes a substrate 100, a first organic layer 110, a first electronic element EU1, a second organic layer 120 and a first lens 130. The electronic device ED may be a display device, such as a vehicle display (as shown in FIG. 3), a wearable device, a smartphone, a tablet or an e-book reader, or the electronic device ED of the present disclosure may be applied to other suitable devices, which is not limited to the above. Taking the embodiment shown in FIG. 3 as an example, FIG. 3 is a schematic diagram showing an electronic device according to an embodiment of the present disclosure installed in a vehicle, wherein the partially enlarged top view of a region FR of the electronic device ED framed by the dotted line in FIG. 3 may correspond FIG. 1. As shown in FIG. 3, the electronic device ED may be installed on a vehicle VE, for example, on the dashboard, the center console or the storage compartment (or referred to as the glove box) beneath a windshield WS, and/or on any other suitable device of the vehicle VE, but not limited herein. The substrate 100 may be a flexible substrate, and the material of the substrate 100 may include, for example, polyimide (PI), polycarbonate (PC), polyethylene terephthalate (PET) or poly(methyl methacrylate) (PMMA), but not limited herein.

The substrate 100 includes a connection portion 100C and at least two main portions 100M, and the connection portion 100C is connected to the at least two main portions 100M. For example, the substrate 100 may include a plurality of connection portions 100C and a plurality of main portions 100M, and each of the connection portions 100C is connected to the adjacent main portions 100M. The main portions 100M may be island-shaped, and the substrate 100 may further include a plurality of substrate openings 100P, each surrounded by the main portions 100M and the connection portions 100C that are adjacent to each other, thereby enabling a stretchable function. Specifically, according to the embodiment shown in FIG. 1, the electronic device ED may have a non-stretched state I and a stretched state II, which are respectively shown on the left and right sides of FIG. 1. When the electronic device ED changes from the non-stretched state I to the stretched state II, the connection portion 100C may deform from a first shape to a second shape. For example, each of the connection portions 100C may be bent, flexed, and/or stretched from a first shape shown on the left side of FIG. 1 to a second shape shown on the right side of FIG. 1. Furthermore, when the electronic device ED changes from the non-stretched state I to the stretched state II, one or more of the main portions 100M (e.g., the main portions 100M located at the lower-left and upper-right in FIG. 1) may rotate clockwise, and another one or more other of the main portions 100M (e.g., the main portions 100M located at the upper-left and lower-right in FIG. 1) may rotate counterclockwise.

The first organic layer 110 is disposed on one of the main portions 100M and includes a first opening OP1, and the first electronic element EU1 is disposed in the first opening OP1. As shown in FIG. 2, the first organic layer 110 may be disposed on each of the main portions 100M and include a plurality of first openings OP1 for respectively accommodating the first electronic elements EU1. The first organic layer 110 may include a transparent, white or black organic photoresist. The first electronic element EU1 may be a light-emitting element, such as an OLED, a mini LED, a micro LED or a quantum dot LED, but not limited herein. When the electronic device ED serves as a display device, the first organic layer 110 may be white to reflect light and enhance luminous efficiency, or the first organic layer 110 may be black to block underlying circuit traces and thereby improve the ambient contrast ratio.

The second organic layer 120 is disposed on the first organic layer 110 and covers the first electronic element EU1, and the first lens 130 is disposed on the second organic layer 120. Specifically, as shown in FIG. 2, the second organic layer 120 covering the first electronic element EU1 may have a top surface 120a that is flat, and the first lens 130 may be disposed on the flat top surface 120a of the second organic layer 120. That is to say, in a direction Z, the top surface 120a of the second organic layer 120 is disposed between the highest point of a top surface 130a of the first lens 130 and a top surface Sa of the first electronic element EU1. The direction Z may be parallel to a normal direction of the substrate 100 and parallel to a top-view direction of the electronic device ED, i.e., the direction Z may be perpendicular to a top surface 100a (or a bottom surface) of the substrate 100. The first lens 130 may be a convex lens configured to focus light, and the material of the first lens 130 may include organic materials such as acrylate, polycarbonate, poly(methyl methacrylate) or other suitable materials. In some embodiments, when the electronic device ED serves as a display device, the transmittance of the second organic layer 120 for visible light may be at least greater than 85%.

Based on the above structural design, the first lens 130 disposed corresponding to the first electronic element EU1 may enhance brightness, reduce power consumption of the electronic element, and extend the service life of the electronic element. Furthermore, since the first lens 130 is disposed on the flat top surface 120a of the second organic layer 120, it may provide improved light-converging effect. For example, the top surface 130a of the first lens 130 that is formed may exhibit a more complete curved shape, which may reduce stray light generation, thereby improving the luminous efficiency of the electronic device ED.

According to the embodiment shown in FIG. 1 and FIG. 2, the electronic device ED may include a plurality of first lenses 130, each of the first lenses 130 may be disposed corresponding to one first electronic element EU1 and overlap the first electronic element EU1 in the direction Z. The term “overlap” mentioned in the present disclosure may refer to either partial or complete overlap. As shown in FIG. 2, in the cross-sectional view of the electronic device ED, a width W1 of the first lens 130 may be greater than a width W2 of the first opening OP1, so as to maximize the light collection of the first lens 130. The width W1 is defined as the maximum width of the first lens 130 in the cross-sectional view, and the width W2 is defined as the maximum width at the top of the first opening OP1 in the same cross-sectional view. For example, the width W1 and the width W2 may be measured along a horizontal direction perpendicular to the direction Z. The first opening OP1 may have a depth D in the direction Z, and the top of the first opening OP1 may be defined as a position located at 0.95*D from the bottom surface thereof.

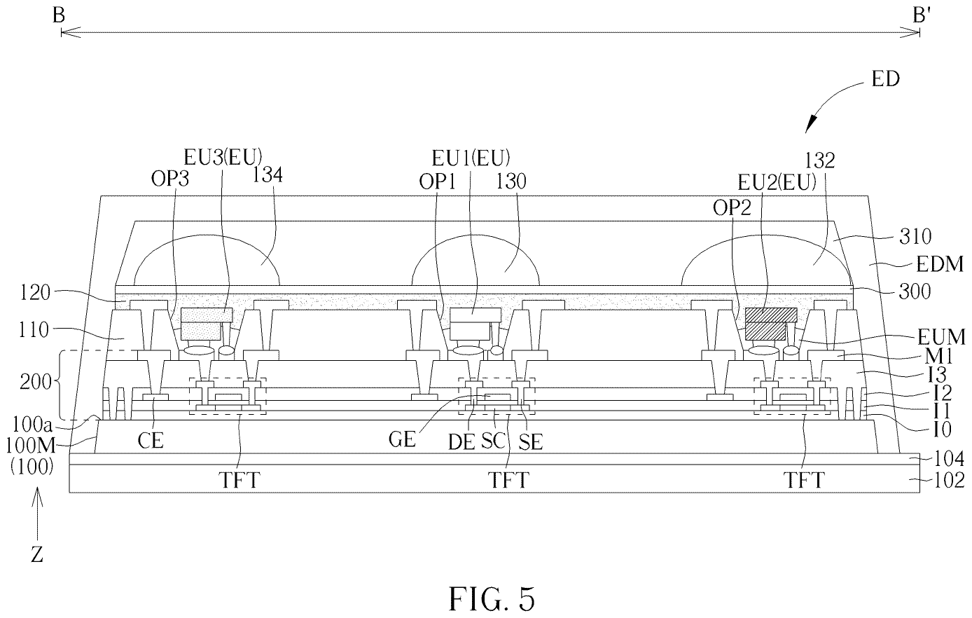

As shown in FIG. 1, in some embodiments, the electronic device ED may include a plurality of electronic elements EU, and the plurality of first lenses 130 may be disposed corresponding to the electronic elements EU in a one-to-one manner. The electronic elements EU may be light-emitting elements and may be disposed on the main portions 100M, and the adjacent ones of the electronic elements EU disposed on the same main portion 100M may form a pixel, wherein a plurality of pixels may be used to display images, but not limited herein. The plurality of electronic elements EU may include a first electronic element EU1, a second electronic element EU2 and a third electronic element EU3, which respectively correspond to sub-pixels of different colors or emit light of different colors, such as (but not limited to) corresponding to a blue sub-pixel, a red sub-pixel and a green sub-pixel. The first organic layer 110 may serve as a pixel definition layer (PDL), which may include a plurality of openings (e.g., the first opening OP1 shown in FIG. 2, and the first opening OP1, second opening OP2, and third opening OP3 shown in FIG. 5) for individually disposing the electronic elements EU.

In this embodiment, the electronic device ED may further include a circuit layer 200 and one or more conductive lines CL. As shown in FIG. 1 and FIG. 2, in the direction Z, the circuit layer 200 may be disposed between one of the main portions 100M and the first organic layer 110, and the circuit layer 200 may include a conductive layer, an insulating layer, a thin-film transistor, and/or a micro-integrated circuit, for driving the electronic elements EU. The conductive line CL may be disposed on the first organic layer 110 and electrically connected to the circuit layer 200 through contact holes in the first organic layer 110, and the first lens 130 may overlap the conductive line CL in the direction Z. A portion of the conductive line CL may be disposed between the first organic layer 110 and the second organic layer 120, and another portion of the conductive line CL may extend across the connection portion 100C of the substrate 100, such that the conductive line CL may span from one main portion 100M to another main portion 100M along the connection portion 100C. The conductive line CL may also be electrically connected to the circuit layers 200 disposed on different main portions 100M.

As shown in FIG. 2, the circuit layer 200 may include a plurality of thin-film transistors TFT, which are electrically connected to the electronic elements EU, respectively, wherein the thin-film transistors TFT may serve, for example, as switching elements or driving elements. Each of the thin-film transistors TFT may include a drain DE, a source SE, a gate GE and a semiconductor layer SC, and an insulating layer I1 may be disposed between the gate GE and the semiconductor layer SC and serve as a gate dielectric layer of the thin-film transistor TFT. Further details of the circuit layer 200 are described below, based on the embodiment shown in FIG. 2 as an example, but the present disclosure is not limited herein. The circuit layer 200 may include an insulating layer I0 (e.g., a buffer layer) disposed on the top surface 100a of the substrate 100. The semiconductor layer SC may be disposed on the insulating layer I0, the insulating layer I1 may be disposed on the semiconductor layer SC, the gate GE may be disposed on the insulating layer I1, an insulating layer I2 may be disposed on the gate GE, and the source SE and the drain DE may be disposed on the insulating layer I2 and electrically connected to the semiconductor layer SC, respectively. An insulating layer I3 may be disposed on the source SE and the drain DE. The materials of the insulating layer I0, the insulating layer I1, and the insulating layer I2 may include inorganic material, such as silicon oxide (SiOx) and/or silicon nitride (SiNx). The material of the insulating layer I3 may include organic material.

According to the embodiments shown in FIG. 1 and FIG. 2, the insulating layers in the circuit layer 200 on one main portion 100M (e.g., the insulating layers I0, I1, I2, and I3) and the insulating layers in the circuit layer 200 on another main portion 100M may be separated from each other and remain independent. In each circuit layer 200, a portion of the insulating layer I3 located near two opposite edges of the circuit layer 200 may extend through the insulating layer I2, the insulating layer I1 and the insulating layer I0 and contact the substrate 100 through the through-holes in these insulating layers, so as to reduce the probability of cracks propagating inward from the edges of the circuit layer 200 and causing damage to the thin-film transistors TFT or other circuits. As shown in FIG. 2, a plurality of through-holes 110H may be formed in regions of the first organic layer 110 corresponding to the connection portion 100C and the substrate opening 100P, such that the portion of the first organic layer 110 on one main portion 100M and the portion of the first organic layer 110 on another main portion 100M may be separated from each other.

In some embodiments, the circuit layer 200 may further include other active elements, passive elements, conductive layers, conductive lines, and/or connecting elements. For example, the circuit layer 200 may include a connecting element CE disposed on the insulating layer I1 and a conductive layer M1 disposed on the insulating layer I3. As shown in FIG. 2, the first organic layer 110 may be disposed on the insulating layer I3 and conductive layer M1 at the topmost layer of the circuit layer 200. Each electronic element EU may include a first electrode E1 and a second electrode E2, the first electrode E1 may be electrically connected to the drain DE through a portion of the conductive layer M1, and the second electrode E2 may be electrically connected to a common electrode through another portion of the conductive layer M1, but not limited herein. In some embodiments, the electronic device ED may further include an encapsulation layer EUM covering the first electrodes E1 and the second electrodes E2 of the electronic elements EU, and the second organic layer 120 may be disposed on the encapsulation layer EUM, but not limited herein. In other embodiments, the encapsulation layer EUM and the second organic layer 120 may be integrally formed. In some embodiments, the electronic device ED may further include a bottom substrate 102, an adhesive layer 104, and an encapsulation layer EDM. The substrate 100 may be attached to the bottom substrate 102 through the adhesive layer 104, and the encapsulation layer EDM may be disposed on the bottom substrate 102 and cover the adhesive layer 104, the substrate 100, the circuit layer 200, the first organic layer 110, the second organic layer 120, and the first lens 130, thereby enhancing the structural stability and reliability of the electronic device ED.

As shown in FIG. 2, in the direction Z, a first thickness T1 of the first lens 130 may be greater than a second thickness T2 of a portion of the second organic layer 120 above the first electronic element EU1, wherein a ratio of the first thickness T1 to the second thickness T2 may be greater than 1 and less than or equal to 30 (i.e., 1<T1/T2≤30). The first thickness T1 is defined as the maximum thickness of the first lens 130, and the second thickness T2 is defined as the maximum thickness of the second organic layer 120 measured in the region above the first electronic element EU1. For example, the second thickness T2 may refer to the thickness of the second organic layer 120 measured in the direction Z from the top surface Sa of the first electronic element EU1 to the bottom surface 130b of the first lens 130. When the ratio of the first thickness T1 to the second thickness T2 is too large, the planarization effect of the second organic layer 120 may be poor, thereby affecting the formation of the first lens 130. When the ratio of the first thickness T1 to the second thickness T2 is too small, the light-converging performance of the first lens 130 may be poor.

In the direction Z, a thickness T3 of the bottom substrate 102 may be greater than the aforementioned second thickness T2, wherein a ratio of the second thickness T2 to the thickness T3 may be greater than or equal to 0.001 and less than 0.01 (i.e., 0.001≤T2/T3<0.01). In some embodiments, a ratio of the second thickness T2 to the sum of the thickness T3 of the bottom substrate 102 and the thickness of the adhesive layer 104 (i.e., T2/(T3+ thickness of the adhesive layer 104)) may also satisfy the above-mentioned proportional relationship. The thickness T3 may be defined as the maximum thickness of the bottom substrate 102 in the direction Z in a region corresponding to the substrate opening 100P. When the ratio of the second thickness T2 to the thickness T3 is too small, the planarization effect of the second organic layer 120 may be poor. When the ratio of the second thickness T2 to the thickness T3 is too large, the supporting strength of the bottom substrate 102 may be insufficient, thereby affecting the structural stability.

The electronic device ED may include a recess RE1 at the connection portion 100C, and the aforementioned second thickness T2 may be less than a depth D1 of the recess RE1 in the direction Z, wherein a ratio of the second thickness T2 to the depth D1 may be greater than or equal to 0.03 and less than or equal to 0.5 (i.e., 0.03≤T2/D1≤0.5). The depth D1 is defined as the depth measured in the direction Z from the top surface 110a of the first organic layer 110 to the bottom of the recess RE1 (i.e., the top surface 100a of the substrate 100). Furthermore, the electronic device ED may include a recess RE2 at the substrate opening 100P, and the second thickness T2 may be less than a depth D2 of the recess RE2 in the direction Z, wherein a ratio of the second thickness T2 to the depth D2 may be greater than or equal to 0.01 and less than or equal to 0.1 (i.e., 0.01≤T2/D2≤0.1). The depth D2 is defined as the depth measured in the direction Z from the top surface 110a of the first organic layer 110 to the bottom of the recess RE2 (i.e., the top surface of the adhesive layer 104 or the bottom substrate 102). When the ratio of the second thickness T2 to the depth D1 or the ratio of the second thickness T2 to the depth D2 is too large, the supporting strength of the substrate 100 may be insufficient, thereby affecting structural stability. When the ratio of the second thickness T2 to the depth D1 or the ratio of the second thickness T2 to the depth D2 is too small, the planarization effect of the second organic layer 120 may be poor.

Some embodiments of the electronic devices ED of the present disclosure will be detailed in the following. In order to simplify the illustration, the same elements in the following would be labeled with the same symbols. The differences between different embodiments are described in detail below, and the same features would not be described redundantly. The embodiments of the present disclosure may be combined and modified with one another.

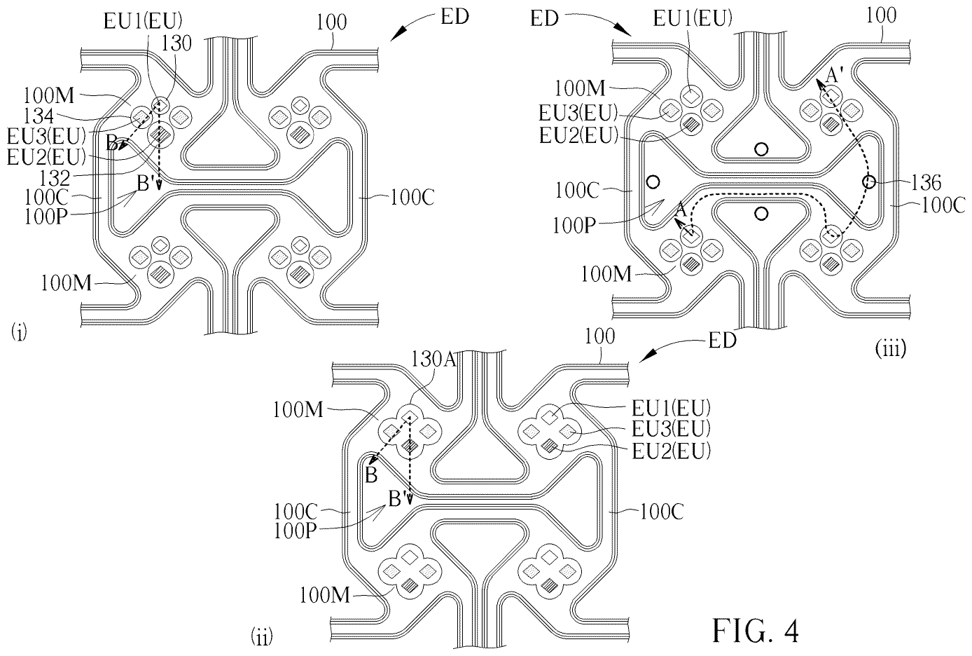

Please refer to FIG. 4 and FIG. 5. FIG. 4 is a partial top view schematic diagram of some variant embodiments of an electronic device according to a first embodiment of the present disclosure, wherein example (i), example (ii) and example (iii) respectively illustrate different variant embodiments. FIG. 5 is a partial cross-sectional schematic diagram of a variant embodiment of an electronic device according to a first embodiment of the present disclosure, wherein FIG. 5 is a cross-sectional view corresponding to the section line B-B′ in example (i) of FIG. 4. As shown in example (i) of FIG. 4 and FIG. 5, the electronic device ED may include the first electronic element EU1, the first lens 130, a second electronic element EU2 and a second lens 132. The second electronic element EU2 is adjacent to the first electronic element EU1 and disposed in a second opening OP2 of the first organic layer 110, and the second lens 132 is disposed on the second electronic element EU2. Specifically, the first electronic element EU1 and the second electronic element EU2 may be disposed on the same main portion 100M of the substrate 100. The first organic layer 110 includes the first opening OP1 and the second opening OP2 adjacent thereto, the first electronic element EU1 is disposed in the first opening OP1, and the second electronic element EU2 is disposed in the second opening OP2. As shown in example (i) of FIG. 4, in the top view of the electronic device ED, an area of the first lens 130 is different from an area of the second lens 132. For example, the size of the first electronic element EU1 may be different from the size of the second electronic element EU2, and the area of the first lens 130 may be smaller than the area of the second lens 132, but not limited herein. The term “area of the lens” mentioned in the present disclosure may be defined as the area of the lens projected onto the substrate 100 in the direction Z.

As show in example (i) of FIG. 4 and FIG. 5, the electronic device ED may further include a third electronic element EU3 and a third lens 134. The third electronic element EU3, together with the first electronic element EU1 and the second electronic element EU2, may be disposed on the same main portion 100M of the substrate 100. The first organic layer 110 further includes a third opening OP3 adjacent to the first opening OP1, and the third electronic element EU3 is disposed in the third opening OP3. An area of the third lens 134 is different from the area of the second lens 132. For example, the size of the first electronic element EU1 may be different from the size of the second electronic element EU2 and/or the third electronic element EU3, and the area of the third lens 134 may be greater than the area of the first lens 130 and smaller than the area of the second lens 132, but not limited herein. In some embodiments, the first lens 130, the second lens 132 and/or the third lens 134 may include organic photoresist with added pigment, such that the light emitted from the first electronic element EU1, the second electronic element EU2, and/or the third electronic element EU3 may exhibit different colors after passing through the corresponding lens, but not limited herein.

In some embodiments, as shown in FIG. 5, the electronic device ED may optionally include an insulating layer 300 and an insulating layer 310. The second organic layer 120 may cover the first electronic element EU1, the second electronic element EU2 and the third electronic element EU3, the insulating layer 300 may be disposed between the second organic layer 120 and the first lens 130 (and/or the second lens 132 and the third lens 134), and the insulating layer 310 may be disposed on the first lens 130, the second lens 132, and the third lens 134. According to the embodiment shown in FIG. 5, on the same main portion 100M, the second organic layer 120 (and/or the insulating layer 300) and the insulating layer 310 may be continuously disposed below and above the first lens 130, the second lens 132 and the third lens 134, respectively. That is to say, the regions between the above lenses may include a connected organic layer and/or insulating layer, but the present disclosure is not limited therein.

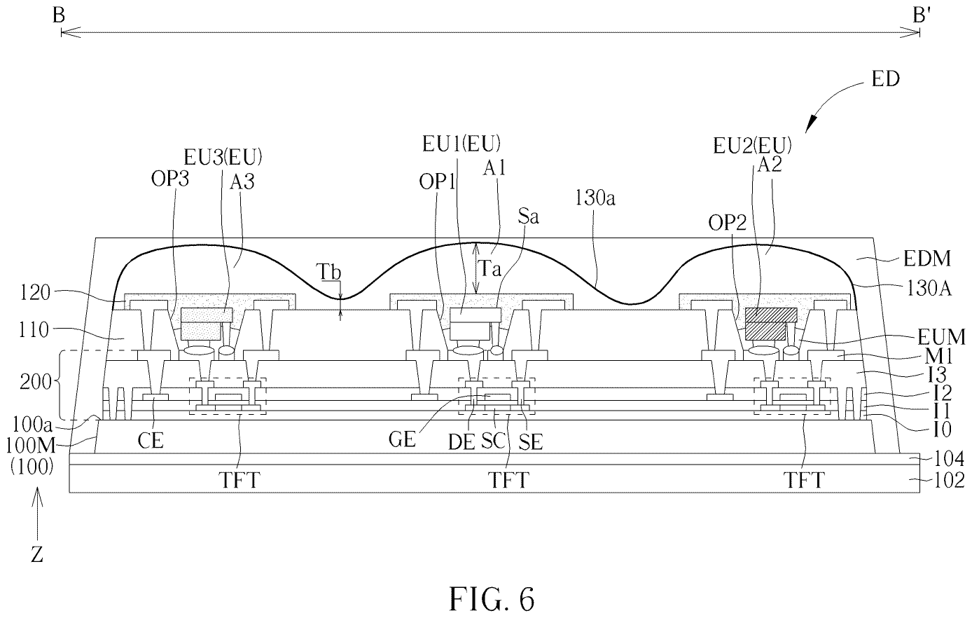

Please refer to example (ii) of FIG. 4 and FIG. 6. FIG. 6 is a partial cross-sectional schematic diagram of another variant embodiment of an electronic device according to a first embodiment of the present disclosure, wherein FIG. 6 is a cross-sectional view corresponding to the section line B-B′ in example (ii) of FIG. 4. As shown in example (ii) of FIG. 4 and FIG. 6, a first lens 130A may be disposed on the first electronic element EU1 and the second electronic element EU2. Specifically, on the main portion 100M, one first lens 130A may be overlapped with both the first electronic element EU1 and the second electronic element EU2 in the direction Z, that is, the electronic elements EU located on the same main portion 100M may share a single first lens 130A. As shown in FIG. 6, the first lens 130A may have a first protrusion A1 that overlaps and corresponds to the first electronic element EU1 in the direction Z and a second protrusion A2 that overlaps and corresponds to the second electronic element EU2 in the direction Z. In the Z direction, the maximum thickness of the portion of the first protrusion A1 located above the first electronic element EU1 may be defined as a thickness Ta, and the maximum thickness of the portion of the first lens 130A that does not correspond to any electronic element EU (i.e., the portion of the first lens 130A not overlapping with any electronic element EU in the direction Z) may be defined as a thickness Tb, wherein the thickness Ta is greater than the thickness Tb. The thickness Ta may be measured in the direction Z from the top surface Sa of the first electronic element EU1 to the top surface 130a of the first protrusion A1. Similarly, the maximum thickness of the portion of the second protrusion A2 located above the second electronic element EU2 may be greater than the aforementioned thickness Tb. In some embodiments, the first lens 130A may further be disposed above the third electronic element EU3 and have a third protrusion A3 that overlaps and corresponds to the third electronic element EU3 in the direction Z, and the maximum thickness of the portion of the third protrusion A3 located above the third electronic element EU3 may be greater than the thickness Tb. As shown in example (ii) of FIG. 4, the top view pattern of the first lens 130A may be an irregular shape configured to correspondingly cover the electronic elements EU on one main portion 100M, but the present disclosure is not limited to the above. In other embodiments, the top view pattern of the first lens 130A may be circular. According to the structural design of the first lens 130A described above, the first lens 130A may be disposed on the electronic elements EU on the same main portion 100M, and the first lens 130A may be integrally formed and manufactured with relatively low requirements for process resolution.

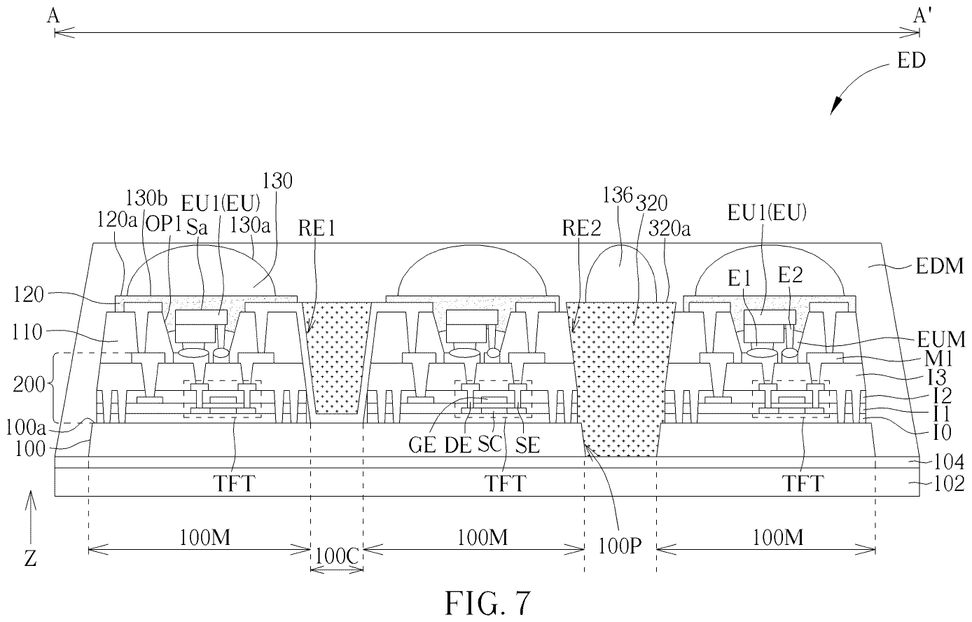

Please refer to example (iii) of FIG. 4 and FIG. 7. FIG. 7 is a partial cross-sectional schematic diagram of still another variant embodiment of an electronic device according to a first embodiment of the present disclosure, wherein FIG. 7 is a cross-sectional view corresponding to the section line A-A′ in example (iii) of FIG. 4. As shown in example (iii) of FIG. 4 and FIG. 7, the electronic device ED may further include one or more dummy lenses 136 disposed on the connection portion 100C and/or the substrate opening 100P of the substrate 100. Specifically, the electronic device ED may include an insulating layer 320 filled in the recess RE1 located on the connection portion 100C and/or the recess RE2 located on the substrate opening 100P. The insulating layer 320 may include an organic material. One or more dummy lenses 136 may be disposed on the insulating layer 320 to improve process uniformity or visual uniformity. In the top view of the electronic device ED, the area of the dummy lens 136 may be different from the area of the first lens 130. For example, the area of the dummy lens 136 may be smaller than the area of the first lens 130. As shown in FIG. 7, a step difference may exist between a top surface 320a of the insulating layer 320 and the top surface 120a of the second organic layer 120 in the direction Z, for example, the top surface 320a of the insulating layer 320 may be lower than the top surface 120a of the second organic layer 120, such that the top of the dummy lens 136 is aligned with the top of the first lens 130, but the present disclosure is not limited thereto. In other embodiments, the top surface 320a of the insulating layer 320 may be higher than or aligned with the top surface 120a of the second organic layer 120.

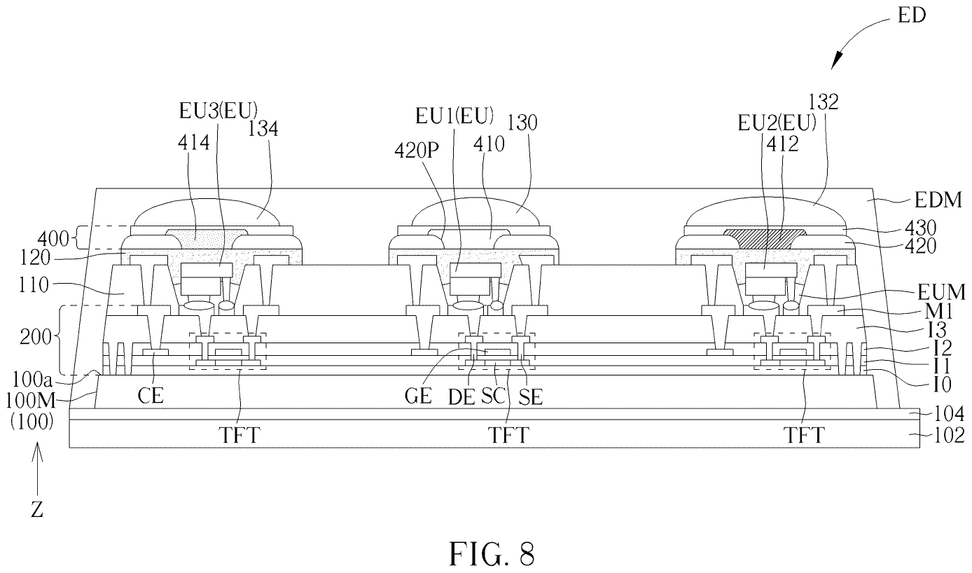

Please refer to FIG. 8, which is a partial cross-sectional schematic diagram of an electronic device according to an embodiment of the present disclosure. As shown in FIG. 8, the electronic device ED may further include a color filter layer 400 disposed between the electronic element EU and the first lens 130, the second lens 132 or the third lens 134. Specifically, the color filter layer 400 may include a first color filter 410 disposed between the first electronic element EU1 and the first lens 130, a second color filter 412 disposed between the second electronic element EU2 and the second lens 132, and a third color filter 414 disposed between the third electronic element EU3 and the third lens 134, so that the light emitted from the first electronic element EU1, the second electronic element EU2 and the third electronic element EU3 may present light of different colors after passing through the corresponding color filter. For example, the first color filter 410, the second color filter 412 and the third color filter 414 may respectively be a blue color filter, a red color filter and a green color filter, but not limited herein.

In this embodiment, the color filter layer 400 may further include a black matrix 420 and an insulating layer 430, and the color filter layer 400 may exhibit anti-reflective optical effects. The black matrix 420 is disposed on the second organic layer 120 and may have a plurality of openings 420P, and each of the openings 420P is overlapped with one of the electronic elements EU. The first color filter 410, the second color filter 412 and the third color filter 414 are individually disposed in one of the openings 420P of the black matrix 420. The insulating layer 430 is disposed on the black matrix 420, the first color filter 410, the second color filter 412 and the third color filter 414. The insulating layer 430 may serve as a planarization layer to fill the underlying irregular topography, and the first lens 130, the second lens 132 and the third lens 134 are disposed on the planar insulating layer 430 and thereby have better light-converging performance. According to the embodiment shown in FIG. 8, on the same main portion 100M, the second organic layer 120 and the insulating layer 430 are not disposed between the regions between any two of the first lens 130, the second lens 132 and third lens 134, wherein the independently separated organic layer and/or insulating layer may reduce the probability of crack generation.

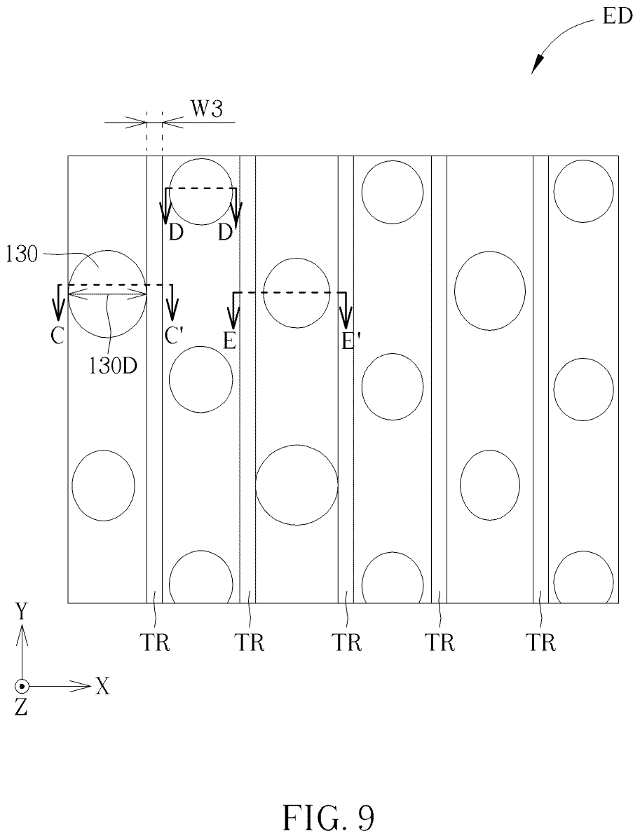

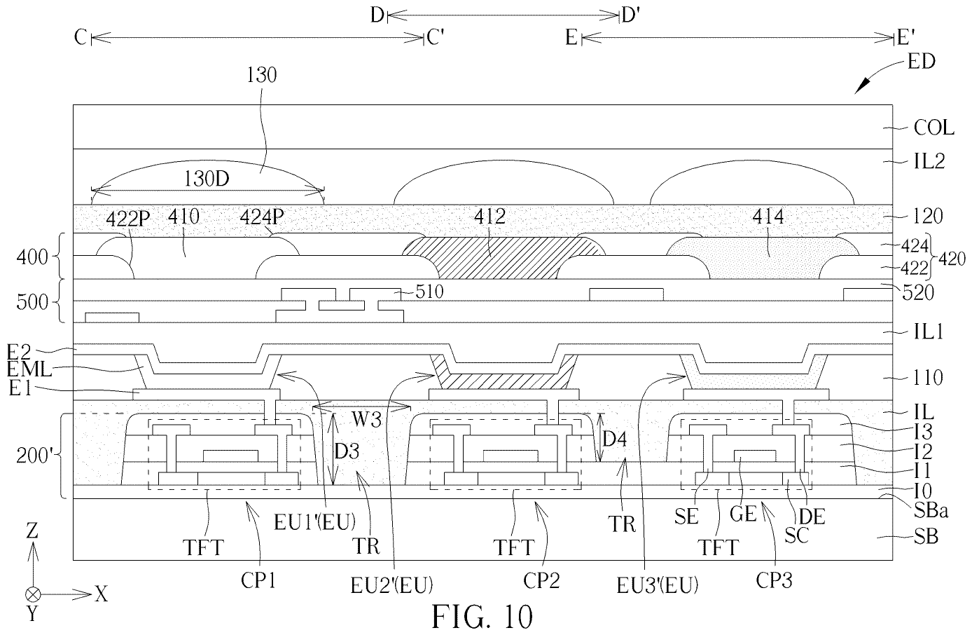

Please refer to FIG. 9 and FIG. 10. FIG. 9 is a partial top view schematic diagram of an electronic device according to a second embodiment of the present disclosure. FIG. 10 is a partial cross-sectional schematic diagram of an electronic device according to a second embodiment of the present disclosure, wherein the cross-sectional view shown in FIG. 10 may correspond to the section line C-C′, the section line D-D′ and the section line E-E′ in FIG. 9. As shown in FIG. 9 and FIG. 10, the electronic device ED may include a substrate SB, a circuit layer 200′, a first electronic element EU1′ and a first lens 130. The substrate SB may be a flexible substrate, and the material of the substrate SB may include, for example, polyimide (PI), polycarbonate (PC), polyethylene terephthalate (PET) or poly(methyl methacrylate) (PMMA), but not limited herein. The circuit layer 200′ is disposed on the substrate SB and includes a first portion CP1, a second portion CP2 and a gap TR (or may be referred to a trench), and the gap TR is disposed between the first portion CP1 and the second portion CP2. The gap TR extends along a direction Y (also referred to as a first direction), and the gap TR may have a width W3 in a direction X (also referred to as a second direction) perpendicular to the direction Y. The width W3 of the gap TR may be defined as the maximum width measured along the direction X. The direction X and the direction Y may be perpendicular to a normal direction of a top surface SBa (or a bottom surface) of the substrate SB, and the direction Z may be perpendicular to both the direction X and the direction Y, i.e., the direction Z may be parallel to the normal direction of the substrate SB and parallel to the top-view direction of the electronic device ED. In some embodiments, the direction Y may be substantially parallel to the bending axis of the electronic device ED. By patterning the circuit layer 200′ to form the first portion CP1 and the second portion CP2 separated by the gap TR, the propagation of cracks from one circuit to another circuit may be prevented during repeated bending of the electronic device ED.

In this embodiment, the circuit layer 200′ may include a plurality of portions (e.g., the first portion CP1, the second portion CP2 and a third portion CP3), and a gap TR exists between adjacent two of the portions. In some embodiments, the corners of the side wall of the gap TR may be arc-shaped to reduce the probability of crack generation, but not limited herein. In some embodiments, based on the routing requirements, a depth D3 of one of the gaps TR in the direction Z may be different from a depth D4 of another gap TR in the direction Z.

The first electronic element EU1′ is disposed on the substrate SB and electrically connected to one of the first portion CP1 and the second portion CP2. For example, as shown in FIG. 10, the first electronic element EU1′ may be electrically connected to the first portion CP1 of the circuit layer 200′. The first lens 130 is disposed on the first electronic element EU1′, and in the direction X, a diameter 130D of the first lens 130 is greater than the width W3 of the gap TR. The diameter 130D of the first lens 130 may be defined as the maximum width of the first lens 130 measured along the direction X. The first lens 130 disposed corresponding to the first electronic element EU1′ may enhance brightness, reduce power consumption of the electronic element, and extend the service life of the electronic element. Furthermore, the smaller width W3 of the gap TR may make the topography under the first lens 130 have a higher flatness during the formation of the first lens 130, so as to have better light-converging performance. When the width W3 of the gap TR is too large and exceeds the diameter 130D of the first lens 130, it may affect the flatness of the first lens 130 during manufacturing, resulting in surface unevenness of the first lens 130 to affect the light-converging performance, and it may further reduce the available space for disposing circuits in the first portion CP1 and the second portion CP2 of the circuit layer 200′.

According to the embodiment shown in FIG. 10, the circuit layer 200′ may include a plurality of thin-film transistors TFT, wherein one of the thin-film transistors TFT is located in the first portion CP1, another thin-film transistor TFT is located in the second portion CP2, and yet another TFT is located in the third portion CP3. The first portion CP1 and the third portion CP3 of the circuit layer 200′ may be located on opposite sides of the second portion CP2 in the direction X. As shown in FIG. 10, the circuit layer 200′ may, for example, include an insulating layer I0 (e.g., a buffer layer), a semiconductor layer SC, an insulating layer I1, a gate GE, an insulating layer I2, a drain DE and a source SE, and an insulating layer I3 sequentially stacked along the direction Z on the top surface SBa of the substrate SB, and the gap TR may be formed in one or more of these insulating layers. However, the structure of the circuit layer 200′ shown in FIG. 10 is merely an example, and the present disclosure is not limited herein. In some embodiments, multiple gaps TR with smaller widths may be formed between the first portion CP1 and the second portion CP2, and a portion of the insulating layer(s) may be disposed between two adjacent gaps TR to provide better structural support, but not limited herein.

In some embodiments, the electronic device ED may further include an insulating layer IL disposed on the circuit layer 200′ and filled in the gaps TR to serve as a planarization layer. The insulating layer IL and the insulating layers in the circuit layer 200′ (e.g., the insulating layer I1, the insulating layer I2 and the insulating layer I3) may include different materials. The insulating layer IL may include an organic material, and the insulating layer I0, the insulating layer I1, the insulating layer I2 and the insulating layer I3 may include inorganic materials such as silicon oxide (SiOx) and/or silicon nitride (SiNx). Since the insulating layer IL filled into the gaps TR may be compressed during bending, the use of organic material may absorb stress, and the insulating layers in the circuit layer 200′ is made of dense inorganic insulating materials to prevent moisture and oxygen from corroding the circuits.

As shown in FIG. 10, the electronic device ED may include a plurality of electronic elements EU, and the electronic device ED may include a plurality of first lenses 130 disposed corresponding to the electronic elements EU in a one-to-one manner. The plurality of electronic elements EU may include the first electronic element EU1′, a second electronic element EU2′ and a third electronic element EU3′, which may be light-emitting elements and respectively correspond to sub-pixels of different colors or emit light of different colors, such as (but not limited to) corresponding to a blue sub-pixel, a red sub-pixel and a green sub-pixel. The first electronic element EU1′, the second electronic element EU2′ and the third electronic element EU3′ may be electrically connected to the thin-film transistors TFT located in the first portion CP1, the second portion CP2 and the third portion CP3 of the circuit layer 200′, respectively. The electronic device ED may further include a first organic layer 110 (e.g., a pixel definition layer) disposed on the insulating layer IL, and the first organic layer 110 may include a plurality of openings for individually disposing the electronic elements EU. Each electronic element EU may include, for example, a first electrode E1, a light-emitting material layer EML and a second electrode E2. The first electrode E1 is disposed on the insulating layer IL and electrically connected to the drain DE, and the light-emitting material layer EML is disposed between the first electrode E1 and the second electrode E2, wherein the second electrode E2 may serve as a common electrode extending across and corresponding to multiple electronic elements EU, but not limited herein. The electronic device ED may further include an insulating layer IL1 disposed on the second electrode E2, which may serve as a planarization layer. In some embodiments, the insulating layer IL1 is a composite layer comprising an inorganic insulating layer, an organic insulating layer and another inorganic insulating layer.

According to the embodiment shown in FIG. 10, the electronic device ED may further include a color filter layer 400 disposed on the circuit layer 200′, and the color filter layer 400 may include a first color filter 410 and a black matrix 420. In the direction Z, the first color filter 410 may be disposed between the first electronic element EU1′ and the first lens 130. The black matrix 420 may be disposed on the gap TR, i.e., the black matrix 420 may be overlap the gap TR in the direction Z. Furthermore, the first lens 130 may overlap the black matrix 420 in the direction Z. According to the embodiment shown in FIG. 10, the color filter layer 400 may further include a second color filter 412 disposed between the second electronic element EU2′ and the first lens 130, and a third color filter 414 disposed between the third electronic element EU3′ and the first lens 130, and the black matrix 420 may include a first light-shielding layer 422 and a second light-shielding layer 424. The first light-shielding layer 422 is disposed on the first organic layer 110 and may have a plurality of openings 422P, each of the openings 422P is overlapped with one of the electronic elements EU. The first color filter 410, the second color filter 412 and the third color filter 414 are respectively disposed in one of the openings 422P. The second light-shielding layer 424 is disposed on the first light-shielding layer 422 and may have a plurality of openings 424P, and each of the openings 424P is overlapped with one of the openings 422P of the first light-shielding layer 422. As shown in FIG. 10, the electronic device ED may further include a second organic layer 120 disposed on the second light-shielding layer 424 and the first color filter 410, the second color filter 412 and the third color filter 414, the second organic layer 120 may serve as a planarization layer to fill the underlying irregular topography, and the first lens 130 may be disposed on the second organic layer 120.

In some embodiments, as shown in FIG. 10, the electronic device ED may further include a touch layer 500 disposed on the electronic elements EU. For example, the touch layer 500 may be disposed between the insulating layer IL1 and the color filter layer 400. The touch layer 500 may include a touch element 510 and one or more insulating layers 520 covering the touch element 510. The touch element 510 may be formed by one or more metal layers, which may be, for example, a metal mesh, but not limited herein. The first light-shielding layer 422 may correspondingly overlap the touch element 510 to shield the touch element 510. In some embodiments, the electronic device ED may further include an insulating layer IL2 covering the first lens 130 and one or more cover layers COL disposed on the insulating layer IL2, but not limited herein.

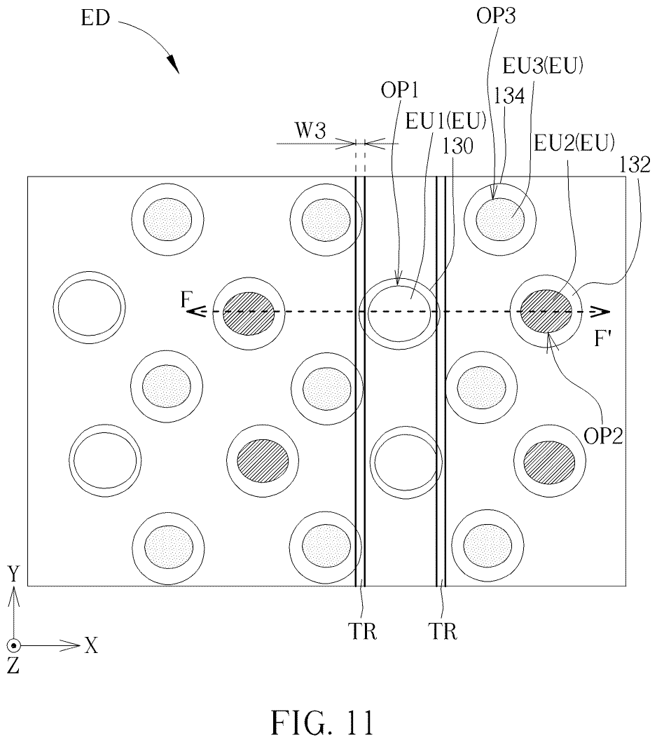

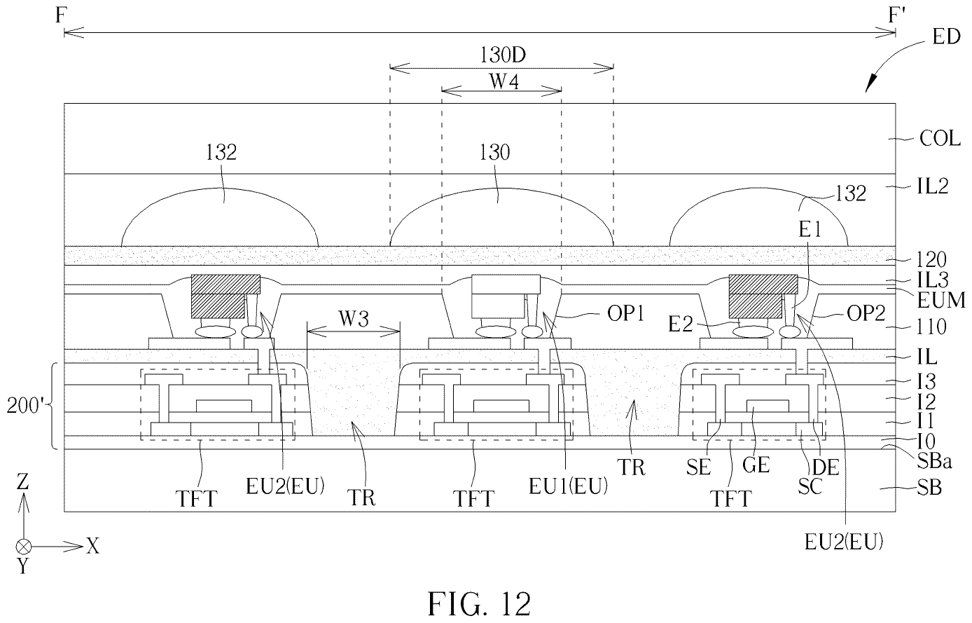

Please refer to FIG. 11 and FIG. 12. FIG. 11 is a partial top view schematic diagram of an electronic device according to a third embodiment of the present disclosure. FIG. 12 is a partial cross-sectional schematic diagram of an electronic device according to a third embodiment of the present disclosure, wherein the cross-sectional view shown in FIG. 12 may correspond to the section line F-F′ in FIG. 11. As shown in FIG. 11 and FIG. 12, the electronic device ED may include a plurality of electronic elements EU, which include a first electronic element EU1, a second electronic element EU2 and a third electronic element EU3. The first electronic element EU1 may be disposed in the first opening OP1 of the first organic layer 110, and a diameter 130D of the first lens 130 may be greater than a width W4 of the first opening OP1, so as to maximize the light collection of the first lens 130. The width W4 may be defined as the maximum width of first opening OP1 measured along the direction X. When the diameter 130D of the first lens 130 is less than the width W4 of the first opening OP1, the light-converging performance of first lens 130 may be poor. Furthermore, the first lens 130 may overlap at least a portion of the gap TR in the direction Z to reduce the visual influence caused by the gap TR, thereby enhancing visual uniformity. As shown in FIG. 12, in the direction X, the diameter 130D of the first lens 130 may be greater than the width W3 of the gap TR, and a radius of the first lens 130 may be greater than or equal to the width W3 of the gap TR (i.e., 0.5*130D≥W3). When the width W3 of the gap TR is greater than the diameter 130D of the first lens 130, it may reduce the available space for disposing the thin-film transistors, and may further result in insufficient structural strength beneath the electronic elements EU during the bonding process, or excessive topographical variation that could lead to circuit abnormalities.

The electronic device ED may further include a second lens 132 and a third lens 134. The second electronic element EU2 is adjacent to the first electronic element EU1 and may be disposed in the second opening OP2 of the first organic layer 110, and the second lens 132 is disposed on the second electronic element EU2. The third electronic element EU3 is adjacent to the first electronic element EU1 and may be disposed in the third opening OP3 of the first organic layer 110, and the third lens 134 is disposed on the third electronic element EU3. As shown in FIG. 11, in the top view of the electronic device ED, the area of the first lens 130 is different from the areas of the second lens 132 and the third lens 134.

In some embodiments, as shown in FIG. 12, the electronic device ED may further include an encapsulation layer EUM covering the first electrodes E1 and the second electrodes E2 of the electronic elements EU and an insulating layer IL3 disposed between the encapsulation layer EUM and the second organic layer 120, but not limited herein. In other embodiments, the encapsulation layer EUM, the insulating layer IL3 and the second organic layer 120 may be integrally formed.

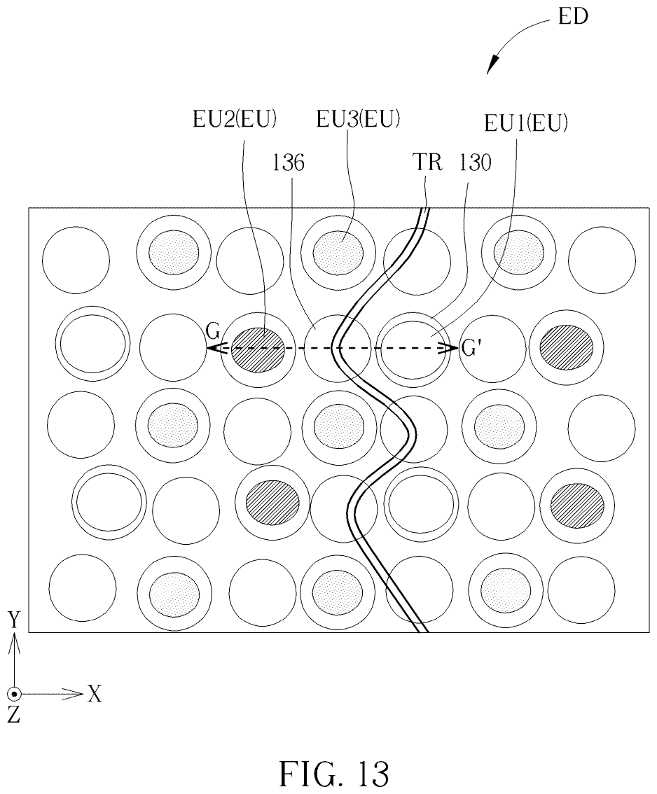

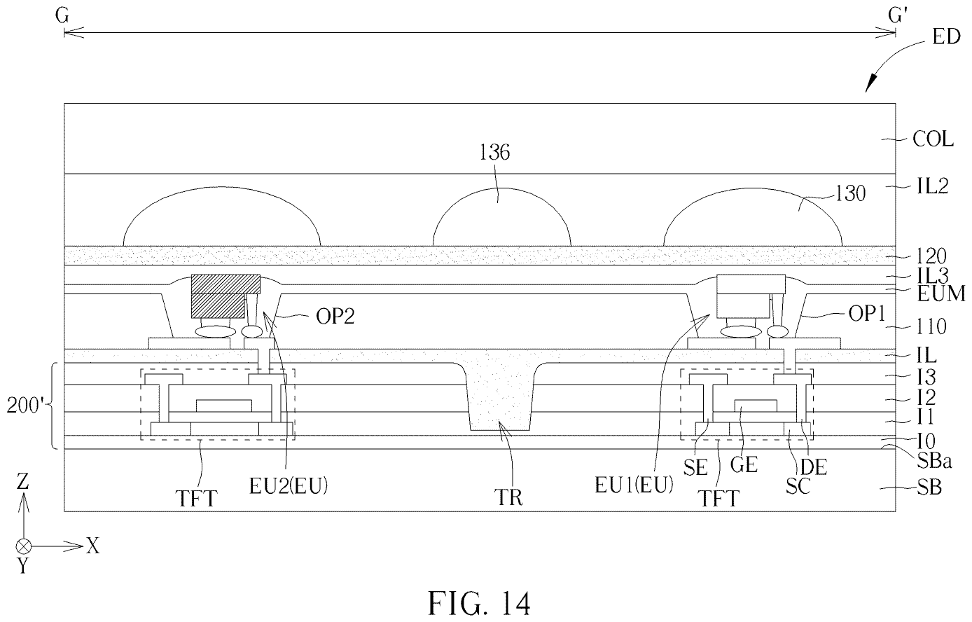

Please refer to FIG. 13 and FIG. 14. FIG. 13 is a partial top view schematic diagram of an electronic device according to a fourth embodiment of the present disclosure. FIG. 14 is a partial cross-sectional schematic diagram of an electronic device according to a fourth embodiment of the present disclosure, wherein the cross-sectional view shown in FIG. 14 may correspond to the section line G-G′ in FIG. 13. As shown in FIG. 13 and FIG. 14, the electronic device ED may further include a dummy lens 136 disposed on the substrate SB and overlapping the gap TR in the direction Z. In the top view of the electronic device ED, an area of the first lens 130 is different from an area of the dummy lens 136. For example, the area of the dummy lens 136 may be smaller than the area of the first lens 130. One or more dummy lenses 136 may be disposed on the second organic layer 120 to improve process uniformity or visual uniformity. As shown in FIG. 13, the gap TR may not extend linearly but instead meander along the direction Y, wherein the gap TR may include curved corners at turning points, and the gap TR may overlap only the dummy lenses 136 and not overlap the first lens 130 in the direction Z, but the present disclosure is not limited herein. In some embodiments, the dummy lens 136 may overlap the gap TR and the black matrix (e.g., the black matrix 420 shown in FIG. 10) in the direction Z, but not limited herein.

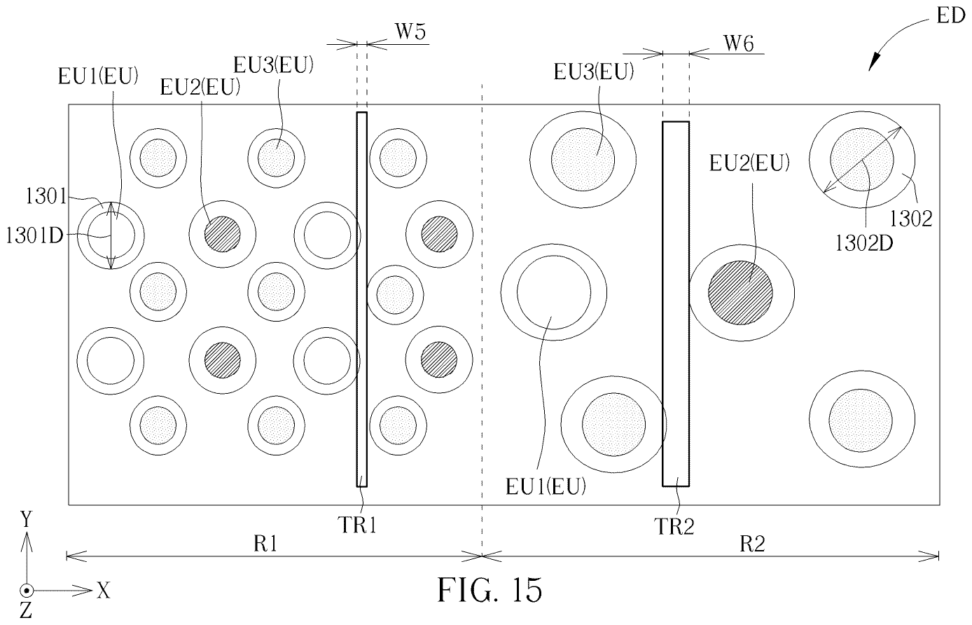

Please refer to FIG. 15, which is a partial top view schematic diagram of an electronic device according to a fifth embodiment of the present disclosure. According to the embodiment shown in FIG. 15, the electronic device ED may include a first region R1 and a second region R2 adjacent to the first region R1. For example, when the electronic device ED is a display device with a camera, the first region R1 may be a display region, and the second region R2 may be a region surrounding the camera. The sizes and pitches of the sub-pixels corresponding to the electronic elements EU in the second region R2 may be greater than the sizes and pitches of the sub-pixels corresponding to the electronic elements EU in the first region R1. As shown in FIG. 15, in the first region R1, the electronic device ED may include a gap TR1 and a plurality of lenses 1301 disposed on the electronic elements EU, and each of the lenses 1301 may overlap the first electronic element EU1, the second electronic element EU2 or the third electronic element EU3 in the direction Z. In the second region R2, the electronic device ED may include a gap TR2 and a plurality of lenses 1302 disposed on the electronic elements EU, and each of the lenses 1302 may overlap the first electronic element EU1, the second electronic element EU2 or the third electronic element EU3 in the direction Z. The diameter 1302D of the lens 1302 may be greater than the diameter 1301D of the lens 1301, and a width W6 of the gap TR2 may be greater than a width W5 of the gap TR1 in the direction X. That is to say, in the top view of the electronic device ED, the area of the lens 1302 located in the second region R2 may be greater than the area of the lens 1301 located in the first region R1.

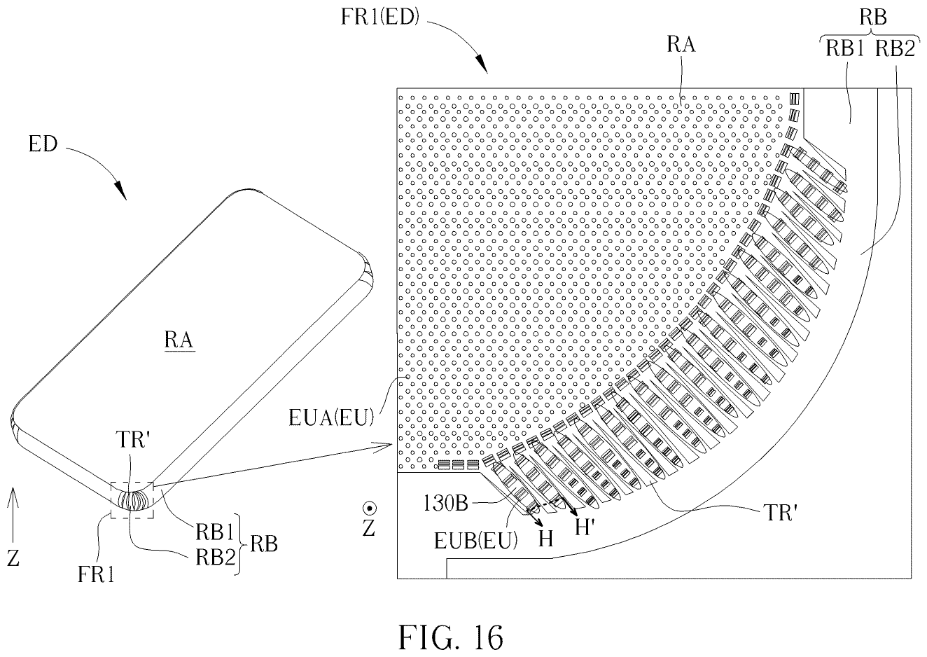

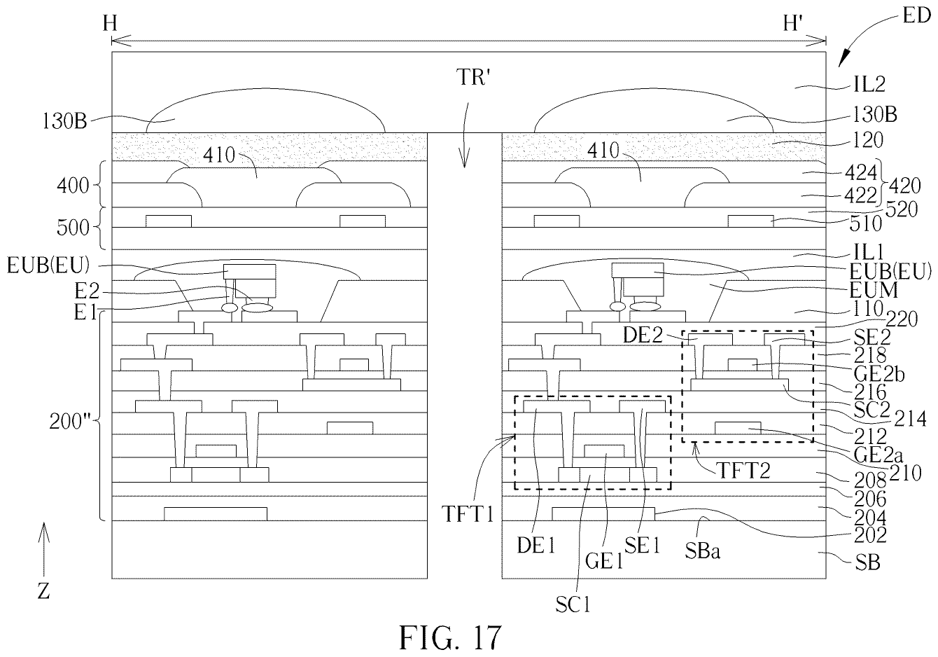

Please refer to FIG. 16 and FIG. 17. FIG. 16 is a schematic diagram of an electronic device according to a sixth embodiment of the present disclosure, wherein the left side of FIG. 16 shows an appearance schematic diagram of the electronic device ED, and the right side of FIG. 16 shows an enlarged top view schematic diagram of the region FR1 of the electronic device ED. FIG. 17 is a partial cross-sectional schematic diagram of an electronic device according to a sixth embodiment of the present disclosure, wherein FIG. 17 is a cross-sectional view corresponding to the section line H-H′ in the top view in FIG. 16. As shown in FIG. 16 and FIG. 17, the electronic device ED may have a first region RA and a second region RB, wherein the second region RB surrounds the first region RA. The second region RB may have a plurality of curved regions RB1 and corner regions RB2, and the corner region RB2 is connected to two of the curved regions RB1. The corner region RB2 may be a two-orientation curved surface with non-zero Gaussian curvature. The curved region RB1 may be regarded as a sidewall region connected to the first region RA, and the corner region RB2 may be regarded as a turning region adjacent to and connected between the sidewalls. In the corner region RB2, the electronic device ED may have a plurality of gaps TR′ to facilitate bending of the corner region RB. The electronic device ED may include a plurality of electronic elements EU and a plurality of lenses 130B. The electronic elements EU may be disposed in the first region RA, the curved regions RB1 and the corner regions RB2 and may be light-emitting elements, and three adjacent electronic elements EU may form one pixel. That is to say, in the top view shown in FIG. 16, the area of one electronic element EU may correspond to the area of one sub-pixel. The lenses 130B may be disposed in the corner region RB2 and/or in the edge region of the first region RA near the corner region RB2, and the lenses 130B are disposed on the electronic elements EU to adjust the light propagation toward the front viewing direction, thereby achieving a viewing angle adjustment effect. In the direction Z, one lens 130B may overlap one or more electronic elements EU, and the lens 130B does not overlap the gaps TR′, i.e., the lens 130B may be disposed between two adjacent gaps TR′.

In some embodiments, three adjacent electronic elements EU may respectively emit blue light, red light and green light. In some embodiments, the area corresponding to the blue sub-pixel may be greater than the area of the red sub-pixel and/or the green sub-pixel, but not limited herein. According to the top view shown in FIG. 16, the plurality of electronic elements EU may include electronic elements EUA and electronic elements EUB, wherein the size of the electronic element EUB may be greater than the size of the electronic element EUA. The electronic elements EUA may be disposed in the first region RA, and the electronic elements EUB may be disposed in the corner region RB, but not limited herein.

As shown in FIG. 17, the electronic device ED may include a substrate SB, and further include a circuit layer 200″, a first organic layer 110, a plurality of electronic elements EU, an insulating layer IL1, a touch layer 500, a color filter layer 400, a second organic layer 120 and an insulating layer IL2 sequentially disposed along the direction Z on the substrate SB, and the gap TR′ may pass through at least a portion of the above-mentioned layers. The layer stack structure above the first organic layer 110 may be referred to the descriptions of the previous embodiments shown in FIG. 10 and FIG. 12, which will not be described redundantly herein. The circuit layer 200″ may include a plurality of first thin-film transistors TFT1 and a plurality of second thin-film transistors TFT2. The first thin-film transistor TFT1 may be electrically connected to the electronic element EU and serve as a driving transistor to drive the electronic element EU, and the second thin-film transistor TFT2 may serve as a switching transistor, wherein the first thin-film transistor TFT1 may be a low-temperature poly-silicon (LTPS) thin-film transistor, and the second thin-film transistor TFT2 may be an indium gallium zinc oxide (IGZO) thin-film transistor, but not limited herein. The first thin-film transistor TFT1 may include a gate GE1, a drain DE1, a source SE1 and a semiconductor layer SC1, and an insulating layer 208 is disposed between the gate GE1 and the semiconductor layer SC1 to serve as a gate dielectric layer. The second thin-film transistor TFT2 may include a gate GE2a, a gate GE2b, a drain DE2, a source SE2 and a semiconductor layer SC2, an insulating layer 212 and an insulating layer 214 are disposed between the gate GE2a and the semiconductor layer SC2 to serve as gate dielectric layers, and an insulating layer 216 may be disposed between the gate GE2b and the semiconductor layer SC2 to serve as another gate dielectric layer.

Further detail structures of the circuit layer 200″ shown in FIG. 17 are described below, but the present disclosure is not limited thereto. The circuit layer 200″ may include a light-shielding layer 202 disposed on the upper surface SBa of the substrate SB, an insulating layer 204 disposed on the light-shielding layer 202, and an insulating layer 206 (e.g., a buffer layer) disposed on the insulating layer 204. The semiconductor layer SC1 is disposed on the insulating layer 206, an insulating layer 208 is disposed on the semiconductor layer SC1, the gate GE1 is disposed on the insulating layer 208, an insulating layer 210 is disposed on the gate GE1, the gate GE2a is disposed on the insulating layer 210, and an insulating layer 212 is disposed on the gate GE2a. The source SE1 and the drain DE1 are disposed on the insulating layer 212 and are individually electrically connected to the semiconductor layer SC1. An insulating layer 214 is disposed on the source SE1 and the drain DE1, the semiconductor layer SC2 is disposed on the insulating layer 214, an insulating layer 216 is disposed on the semiconductor layer SC2, the gate GE2b is disposed on the insulating layer 216, and an insulating layer 218 is disposed on the gate GE2b. The source SE2 and the drain DE2 are disposed on the insulating layer 218 and are individually electrically connected to the semiconductor layer SC2. An insulating layer 220 is disposed on the source SE2 and the drain DE2. The first electrode E1 of each electronic element EU may be electrically connected to the drain DE1 through the conductive layer in the circuit layer 200″, and the second electrode E2 of each electronic element EU may be electrically connected to a common electrode, but not limited herein.

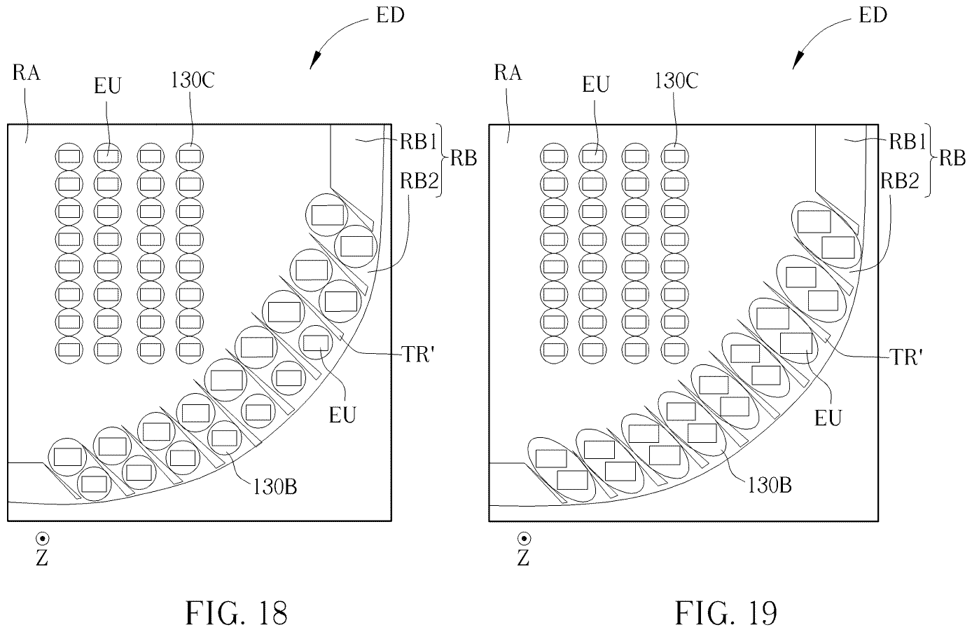

Please refer to FIG. 18 and FIG. 19. FIG. 18 is a partial top view schematic diagram of a variant embodiment of an electronic device according to a sixth embodiment of the present disclosure. FIG. 19 is a partial top view schematic diagram of another variant embodiment of an electronic device according to a sixth embodiment of the present disclosure. According to the embodiments shown in FIG. 18 and FIG. 19, the electronic device ED may include a plurality of lenses 130B and a plurality of lenses 130C, the lenses 130B are disposed in the corner region RB2, and the lenses 130C are disposed in the first region R1. In the top view of the electronic device ED, the area of the lens 130B may be different from the area of the lens 130C. For example, the area of the lens 130B may be greater than the area of the lens 130C. In some embodiments, as shown in FIG. 18, in the direction Z, each lens 130B may overlap one electronic element EU, and each lens 130C may overlap one electronic element EU. In other embodiments, as shown in FIG. 19, in the direction Z, the number of the electronic elements EU overlapped with one lens 130B may be different from the number of the electronic elements EU overlapped with one lens 130C. For example, the number of the electronic elements EU overlapped with one lens 130B may be greater than the number of the electronic elements EU overlapped with one lens 130C.

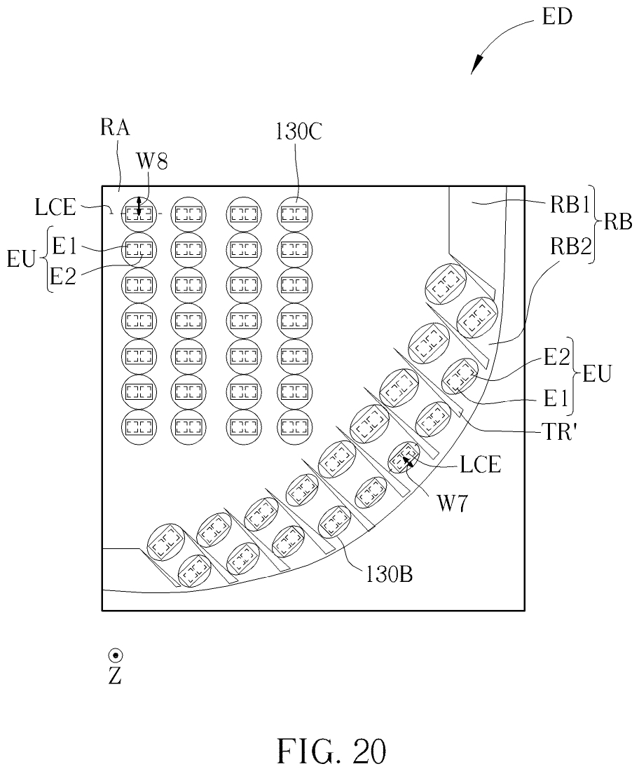

Please refer to FIG. 20, which is a partial top view schematic diagram of still another variant embodiment of an electronic device according to a sixth embodiment of the present disclosure. According to the electronic device ED shown in FIG. 20, each electronic element EU may include a first electrode E1 and a second electrode E2, and in the top view of the electronic device ED, an extension line LCE may be obtained by connecting the centers of the first electrode E1 and the second electrode E2. In a direction perpendicular to the extension line LCE, a width W7 may be obtained by measuring the distance from the edge of the lens 130B to the extension line LCE, and a width W8 may be obtained by measuring the distance from the edge of the lens 130C to the extension line LCE, wherein the width W7 is different from the width W8. For example, the width W7 may be less than width W8, but not limited herein. In this embodiment, in the corner region RB2, the arrangement and shape of the lenses 130B may be constrained by the gaps TR′ and thus require corresponding adjustments, resulting in the difference between the width W7 and the width W8.

From the above description, according to the electronic devices of the embodiments of the present disclosure, the first lens is disposed corresponding to the electronic element, which may provide the light-converging effect and enhance brightness, thereby reducing the power consumption of the electronic element. Furthermore, through the configuration of various lenses and the design of the organic layers, the substrate, the circuit layer, and/or other layer structures in the electronic device, better light-converging performance may be achieved, thereby improving the luminous efficiency and reliability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate comprising a connection portion and at least two main portions, the connection portion being connected to the at least two main portions;
a first organic layer disposed on one of the at least two main portions and comprising a first opening;
a first electronic element disposed in the first opening;
a second organic layer disposed on the first organic layer and covering the first electronic element; and
a first lens disposed on the second organic layer.

2. The electronic device according to claim 1, wherein a first thickness of the first lens is greater than a second thickness of a portion of the second organic layer above the first electronic element.

3. The electronic device according to claim 2, wherein a ratio of the first thickness to the second thickness is greater than 1 and less than or equal to 30.

4. The electronic device according to claim 1, wherein in a cross-sectional view of the electronic device, a width of the first lens is greater than a width of the first opening.

5. The electronic device according to claim 1, wherein a top surface of the second organic layer is disposed between a highest point of a top surface of the first lens and a top surface of the first electronic element.

6. The electronic device according to claim 1, further comprising a second electronic element adjacent to the first electronic element and disposed in a second opening of the first organic layer, wherein the first lens is further disposed on the second electronic element.

7. The electronic device according to claim 1, further comprising:
a second electronic element adjacent to the first electronic element and disposed in a second opening of the first organic layer; and
a second lens disposed on the second electronic element.

8. The electronic device according to claim 7, wherein in a top view of the electronic device, an area of the first lens is different from an area of the second lens.

9. The electronic device according to claim 1, wherein the substrate is a flexible substrate.

10. The electronic device according to claim 1, which has a non-stretched state and a stretched state, wherein when the electronic device changes from the non-stretched state to the stretched state, one of the at least two main portions rotates clockwise and another one of the at least two main portions rotates counterclockwise.

11. The electronic device according to claim 1, which has a non-stretched state and a stretched state, wherein when the electronic device changes from the non-stretched state to the stretched state, the connection portion deforms from a first shape to a second shape.

12. An electronic device, comprising:
a substrate;
a circuit layer disposed on the substrate, comprising a first portion, a second portion, and a gap disposed between the first portion and the second portion;
a first electronic element disposed on the substrate and electrically connected to one of the first portion and the second portion; and
a first lens disposed on the first electronic element,
wherein the gap extends along a first direction, and a diameter of the first lens is greater than a width of the gap in a second direction perpendicular to the first direction.

13. The electronic device according to claim 12, further comprising a color filter layer disposed on the circuit layer, wherein the color filter layer comprises:
a color filter disposed between the first electronic element and the first lens; and
a black matrix disposed on the gap.

14. The electronic device according to claim 13, wherein the first lens overlaps the black matrix in a normal direction of the substrate.

15. The electronic device according to claim 12, wherein the first lens overlaps at least a portion of the gap in a normal direction of the substrate.

16. The electronic device according to claim 12, wherein a radius of the first lens is greater than or equal to the width of the gap in the second direction.

17. The electronic device according to claim 12, further comprising a dummy lens disposed on the substrate and overlapping the gap in a normal direction of the substrate.

18. The electronic device according to claim 17, wherein in a top view of the electronic device, an area of the first lens is different from an area of the dummy lens.

19. The electronic device according to claim 12, further comprising a first insulating layer disposed on the circuit layer and filled in the gap, wherein the circuit layer further comprises a second insulating layer, and the first insulating layer and the second insulating layer comprise different materials.

20. The electronic device according to claim 19, wherein the first insulating layer comprises an organic material, and the second insulating layer comprises an inorganic material.
